(19) United States
(12) Patent Application Publication
(10) Pub. No.: US 2015/0380330 A1
(43) Pub. Date: Dec. 31, 2015

(54) PACKAGE SUBSTRATE, PACKAGE, AND ELECTRONIC DEVICE

(71) Applicant: Asahi Glass Company, Limited, Chiyoda-ku (JP)

(72) Inventors: Yoko MITSUI, Chiyoda-ku (JP); Satoshi TAKEDA, Chiyoda-ku (JP)

(73) Assignee: Asahi Glass Company, Limited, Chiyoda-ku (JP)

(21) Appl. No.: 14/738,018

(22) Filed: Jun. 12, 2015

(30) Foreign Application Priority Data
Jun. 27, 2014 (JP) 2014-132671
Mar. 19, 2015 (JP) 2015-056128

(51) Int. Cl. H01L 23/053; H05K 1/02; H01L 23/08; H01L 33/48; H01L 41/053

(52) U.S. Cl. CPC H01L 23/053; H01L 33/483; H01L 41/053; H01L 23/08; H05K 1/0271

(57) ABSTRACT

A package substrate includes a recessed part and a step part disposed at a periphery thereof, and a lid body is bonded to the step part to cover the recessed part via a bonding layer containing a glass and an electromagnetic wave absorbent material. A ratio (w₁/h₁) of a width (w₁) to a height (h₁) of the step part of the package substrate is 1.0 or more.

### CROSS-REFERENCE TO RELATED APPLICATIONS

This application is based upon and claims the benefit of priority from Japanese Patent Application No. 2014-132671 filed on Jun. 27, 2014 and Japanese Patent Application No. 2015-056128 filed on Mar. 19, 2015; the entire contents of which are incorporated herein by reference.

### FIELD

Embodiments described herein relate to a package substrate, a package, and an electronic device.

### BACKGROUND

In an electronic device accommodating electronic elements such as a semiconductor light-emitting element and a piezoelectric vibrator, a package is used in which a package substrate having a recessed part and a plate-state lid body disposed to cover the recessed part are bonded at a step part forming the recessed part.

As a bonding method between the package substrate and the lid body, a method using a metal adhesive agent is known. As the metal adhesive agent, for example, an AuSn alloy, a high melting point solder, an Ag solder are used. When the metal adhesive agent is used, the package substrate and the lid body are stacked via the metal adhesive agent, and thereafter, a whole of them are heat treated to be bonded (for example, WO2011/013581).

Besides, as another bonding method, a method using a low-melting point glass is known. When the low-melting point glass is used, the package substrate and the lid body are stacked via the low-melting point glass, and thereafter, a whole of them are also heat treated to be bonded (for example, JP-A 2003-060470).

Further, as still another bonding method, a method is known in which laser light is irradiated only at a bonding part instead of performing the heat treatment of the whole of the package substrate and the lid body including the bonding part. According to the bonding method as stated above, a temperature increase is suppressed except the bonding part, and therefore, it is easy to suppress lowering of properties of electronic elements accommodated in the package (for example, JP-A 2013-038727).

However, in case of the method irradiating the laser light, cracks and peelings are easy to occur at the bonding part between the package substrate having the recessed part and the lid body, and it is difficult to manufacture a package excellent in protection of an accommodated object such as the electronic element. In particular, the cracks are easy to occur at a part where the step part forming the recessed part of the package substrate is bonded within the lid body, and the peelings are easy to occur between the step part and the lid body. When the cracks and the peelings occur at the bonding part, the lid body is easy to be detached by a contact and an impact from outside, and the protection of the electronic elements or the like accommodated in the recessed part becomes insufficient.

### SUMMARY

The present invention is made to solve the above-stated problems, and an object thereof is to provide a package substrate where a lid body is bonded to a part of a step part which forms a recessed part by irradiation of laser light, and occurrences of cracks and peelings at a bonding part are suppressed. Besides, another object of the present invention is to provide a package in which a lid body is bonded to the package substrate.

A package substrate according to the present invention relates to the package substrate including: a recessed part; and a step part disposed at a periphery thereof, wherein a lid body is bonded to the step part to cover the recessed part via a bonding layer containing a glass and an electromagnetic wave absorbent material. The package substrate according to the present invention is characterized in that a ratio (w₁/h₁) of a width (w₁) to a height (h₁) of the step part is 1.0 or more.

A package according to the present invention includes: a package substrate, a lid body, and a bonding layer. The package substrate includes a recessed part and a step part disposed at a periphery thereof, wherein a ratio (w₁/h₁) of a width (w₁) to a height (h₁) of the step part is 1.0 or more. The lid body is disposed to face the package substrate to cover the recessed part of the package substrate. The bonding layer contains a glass and an electromagnetic wave absorbent material, and bonds the package substrate and the lid body at the step part of the package substrate.

According to the present invention, a ratio (w₁/h₁) of a width (w₁) to a height (h₁) of a step part of a package substrate is set to be 1.0 or more, and thereby it is possible to obtain a package in which protection of an accommodated object is good by suppressing occurrences of cracks and peelings at a bonding part when a lid body is bonded by irradiation of laser light.

### BRIEF DESCRIPTION OF THE DRAWINGS

FIG. 1 is a sectional view illustrating an embodiment of an electronic device.

FIG. 2 is a sectional view illustrating an embodiment of an electronic device including a glass layer.

FIG. 3 is a sectional view illustrating a state before a package substrate where an electronic element is accommodated and a lid body where a bonding material layer is formed are stacked.

FIG. 4 is a sectional view illustrating a state after the package substrate where the electronic element is accommodated and the lid body where the bonding material layer is formed are stacked.

FIG. 5 is a view illustrating an irradiation method of laser light.

### DETAILED DESCRIPTION

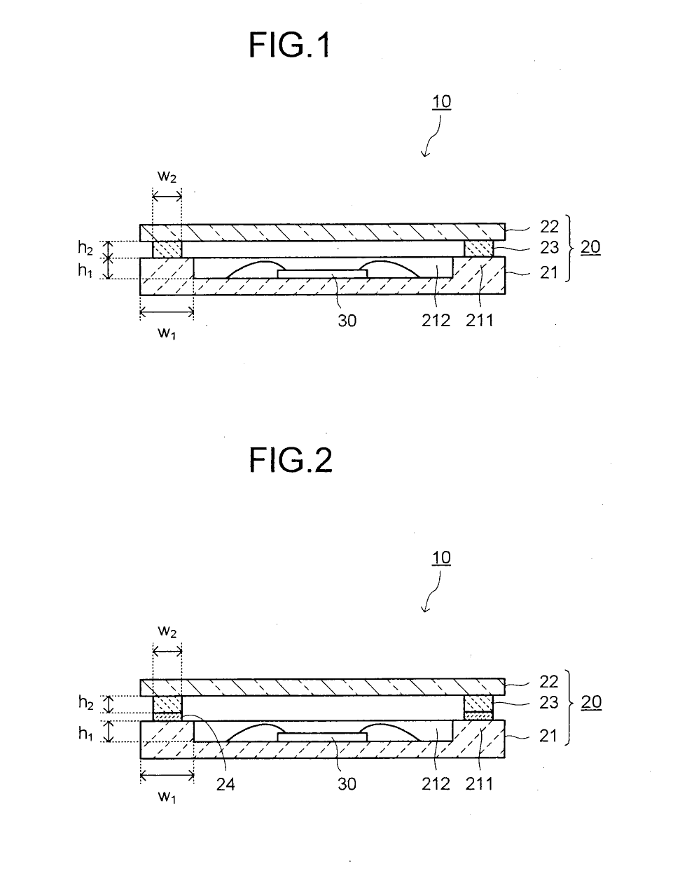

FIG. 1 is a sectional view illustrating an embodiment of an electronic device 10. The electronic device 10 includes a package 20 and an electronic element 30 accommodated in the package 20. Besides, the package 20 includes a package substrate 21, a lid body 22, and a bonding layer 23.

The package substrate 21 is one, for example, having a square planar shape, and a step part 211 has an annular shape along an outer edge part, and a recessed part 212 where the electronic element 30 is accommodated is formed inside the step part 211. The step part 211 is integrally provided at the package substrate 21 and is constituted by the same material as the other parts. The lid body 22 has, for example, a square planar shape similar to the planar shape of the package substrate 21, and is a flat plate state without a recessed part and a step part, and is disposed to face the package substrate 21 to cover the step part 211 and the recessed part 212 of the package substrate 21.

The bonding layer 23 is disposed between the step part 211 of the package substrate 21 and a part of the lid body 22 facing the step part 211, to bond between the package substrate 21 and the lid body 22. The bonding layer 23 includes at least a glass and an electromagnetic wave absorbent material.

The package 20 is one where the package substrate 21 and the lid body 22 are bonded by the bonding layer 23 which includes at least the glass and the electromagnetic wave absorbent material, and the bonding between the package substrate 21 and the lid body 22 is performed by irradiation of laser light.

At the package 20 as described below, a shape of the step part 211 of the package substrate 21 is a predetermined shape, further preferably, a shape of the bonding layer 23 is a predetermined shape, and thereby, occurrences of cracks and peelings at the bonding part are suppressed. Strength of the bonding part is thereby improved, and breakage and lowering of properties of the electronic element 30 accommodated therein are thereby suppressed. Besides, the shape of the step part 211 is made to be a complete annular state, and thereby, it is possible to improve airtightness.

Here, as the cracks at the bonding part, there can be cited the cracks at the bonding layer 23, the package substrate 21, and the lid body 22. As the cracks at the package substrate 21, for example, there can be cited the cracks at the step part 211 where the bonding layer 23 is bonded. As the cracks at the lid body 22, for example, there can be cited the cracks at a part at a surface side where the bonding layer 23 is bonded. Besides, as the peelings at the bonding part, there can be cited the peeling between the package substrate 21 and the bonding layer 23 or between the lid body 22 and the bonding layer 23.

A ratio (w₁/h₁) of a width (w₁) to a height (h₁) of the step part 211 is 1.0 or more. Here, the height (h₁) of the step part 211 is a length in a height direction from a position at a bottom surface of the recessed part 212 to a position at a tip surface of the step part 211. Besides, the width (w₁) of the step part 211 is a length of the step part 211 in a vertical direction relative to the height direction.

When the ratio (w₁/h₁) is less than 1.0, the width (w₁) becomes relatively narrow relative to the height (h₁) of the step part 211, and therefore, heat generated at the bonding layer 23 at a bonding time is difficult to go away to the other parts through the step part 211, and is easy to go away to the lid body 22. As a result, a temperature of the lid body 22, particularly a temperature in a vicinity of a part where the bonding layer 23 is bonded increases, and the cracks and the peelings are easy to occur.

When the ratio (w₁/h₁) is 1.0 or more, the width (w₁) becomes relatively wide relative to the height (h₁) of the step part 211, and therefore, the heat generated at the bonding layer 23 at the bonding time is easy to go away to the other parts through the step part 211, and the temperature increase at the lid body 22 is suppressed. The occurrences of the cracks and the peelings are thereby suppressed.

The ratio (w₁/h₁) is preferably 1.5 or more, more preferably 2.0 or more, and further preferably 3.0 or more from a viewpoint that the heat generated at the bonding layer 23 at the bonding time is made easy to go away to the other parts through the step part 211. On the other hand, when the ratio (w₁/h₁) becomes excessively high, an area of the recessed part 212 decreases in accordance with increase of the width (w₁) of the step part 211, and thereby, it becomes difficult to accommodate the electronic element 30. Therefore, it is preferably 15.0 or less, more preferably 7.0 or less, and further preferably 4.0 or less.

Note that the width (w₁) of the step part 211 is not necessarily constant in a circumferential direction of the step part 211. For example, a case is conceivable in which the width at a corner part in the circumferential direction is made wider than the other parts. In such a case, it is preferable that the above-stated ratio (w₁/h₁) is satisfied at a part where the width (w₁) becomes the narrowest in the circumferential direction. Normally, the height (h₁) is constant in the circumferential direction, and therefore, the above-stated ratio (w₁/h₁) is satisfied also at the other parts in the circumferential direction as long as the above-stated ratio (w₁/h₁) is satisfied at the part where the width (w₁) becomes the narrowest in the circumferential direction.

Besides, as the package substrate 21, it is not necessary that the step part 211 is provided in a complete annular state, and the step part 211 may be discontinuously provided. As the package substrate 21 as stated above, for example, there can be cited one where the step part 211 is held only at a pair of facing outer edge parts of the package substrate 21 having the square planar shape. As for the package substrate 21 as stated above, it is preferable that the above-stated ratio (w₁/h₁) is satisfied at a part where the step part 211 is provided and the width (w₁) becomes the narrowest.

Besides, the width (w₁) of the step part 211 is not necessarily constant in the height direction of the step part 211, and for example, the width (w₁) may gradually decrease from a root part toward a tip part of the step part 211. In such a case, it is preferable that the above-stated ratio (w₁/h₁) is satisfied at a part where the width (w₁) becomes the narrowest, namely, at a tip part of the step part 211.

A ratio ((w₁/h₁)/(w₂·h₂)) of the ratio (w₁/h₁) of the width (w₁) to the height (h₁) of the step part 211 to a product (w₂·h₂) of a width (w₂) and a height (h₂) of the bonding layer 23 is preferably 100 [mm⁻²] or more. Here, the height (h₂) of the bonding layer 23 is a length in a thickness direction of the bonding layer 23. The width (w₂) of the bonding layer 23 is a length in a vertical direction relative to the thickness direction of the bonding layer 23.

When the ratio ((w₁/h₁)/(w₂·h₂)) is less than 100 [mm⁻²], a cross-sectional area of the bonding layer 23 is relatively large, and therefore, the heat generated at the bonding layer 23 at the bonding time is difficult to go away to the other parts through the step part 211, and is easy to go away to the lid body 22. When the ratio ((w₁/h₁)/(w₂·h₂)) is 100 [mm⁻²] or more, the cross-sectional area of the bonding layer 23 is relatively small, and therefore, it is preferable because the heat generated at the bonding layer 23 at the bonding time is easy to go away to the other parts through the step part 211.

The ratio ((w₁/h₁)/(w₂·h₂)) is preferably 200 [mm⁻²] or more, more preferably 300 [mm⁻²] or more, and further preferably 500 [mm⁻²] or more from the viewpoint that the heat generated at the bonding layer 23 at the bonding time is made easy to go away to the other parts through the step part 211.

On the other hand, when the ratio ((w₁/h₁)/(w₂·h₂)) becomes excessively high, the area of the recessed part 212 decreases in accordance with the increase of the width (w₁) of the step part 211, it becomes thereby difficult to accommodate the electronic element 30, and there is a possibility in which bonding strength becomes insufficient in accordance with decrease of the cross sectional area (w₂·h₂) of the bonding layer. Therefore, it is preferably 5000 [mm⁻²] or less, more preferably 2500 [mm⁻²] or less, and further preferably 1000 [mm⁻²] or less.

The width (w₁) of the step part 211 is preferably 0.5 mm or more, more preferably 1.0 mm or more, and further preferably 1.5 mm or more from the viewpoint that the heat generated at the bonding layer 23 at the bonding time is made easy to go away to the other parts through the step part 211. Besides, the width (w₁) of the step part 211 is preferably 5.0 mm or less, more preferably 4.0 mm or less, and further preferably 3.0 mm or less from a viewpoint of securing an area to accommodate the electronic element 30.

Besides, the width (w₁) of the step part 211 is preferably 20% or less, more preferably 15% or less, and further preferably 10% or less of a package substrate size. Specifically, in case of a 7 mm square size package, the width (w₁) of the step part 211 is preferably 1.4 mm or less, in case of a 20 mm square size package, the width (w₁) of the step part 211 is preferably 4 mm or less.

The height (h₁) of the step part 211 is preferably 0.2 mm or more, more preferably 0.4 mm or more, and further preferably 0.6 mm or more from a viewpoint of securing a height to accommodate the electronic element 30. Besides, the height (h₁) of the step part 211 is preferably 1.5 mm or less, more preferably 1.0 mm or less, and further preferably 0.8 mm or less from the viewpoint that the heat generated at the bonding layer 23 at the bonding time is made easy to go away to the other parts through the step part 211.

The width (w₂) of the bonding layer 23 is preferably 0.1 mm or more, more preferably 0.15 mm or more, and further preferably 0.2 mm or more from a viewpoint of a printability of a bonding material layer forming the bonding layer 23 and a viewpoint of securing the bonding strength. Besides, the width (w₂) of the bonding layer 23 is preferably 1.0 mm or less, more preferably 0.8 mm or less, and further preferably 0.5 mm or less from a viewpoint of reducing a heat quantity moving from the bonding layer 23 to the other parts at the bonding time.

The height (h₂) of the bonding layer 23 is preferably 1 μm or more, more preferably 3 μm or more, and further preferably 5 μm or more from a viewpoint of securing the bonding strength. Besides, the height (h₂) of the bonding layer 23 is preferably 50 μm or less, more preferably 25 μm or less, and further preferably 15 μm or less from the viewpoint of reducing the heat quantity moving from the bonding layer 23 to the other parts at the bonding time.

The package 20 as stated above is suitable for accommodation of a relatively small electronic element 30, and is suitable for accommodation of a semiconductor light-emitting element, a piezoelectric vibrator, and so on. Besides, the package 20 of the present invention is particularly suitable for the accommodation of the semiconductor light-emitting element or the like generating ultraviolet ray because the bonding layer 23 is constituted by an inorganic material and deterioration caused by the irradiation of the ultraviolet ray is small.

The package 20 preferably has a square planar shape whose length of one edge is 50 mm or less, and more preferably has a square planar shape whose length of one edge is 30 mm or less. In case of the small-sized package 20 as stated above, large bonding strength is not required for the bonding layer 23, and therefore, it is possible to narrow down the width (w₂) of the bonding layer 23 and to lower the height (h₂) of the bonding layer 23. Therefore, it is possible to make it easy to reduce the heat quantity moving from the bonding layer 23 to the other parts at the bonding time, and to suppress the occurrences of the cracks and the peelings.

As illustrated in FIG. 2, it is preferable to provide a glass layer 24 between the step part 211 and the bonding layer 23 at the package 20 to improve planarity or for heat insulation according to need.

For example, when the planarity of a surface of the step part 211 is low, a temperature distribution is easy to occur such that heat generation locally occurs or the like when the laser light is irradiated. In such a case, it is preferable to provide the glass layer 24 to improve the planarity to thereby suppress the occurrence of the temperature distribution.

Besides, for example, when heat conductivity of a material constituting the step part 211 is high, the heat generated by the irradiation of the laser light is easy to go away to the other parts through the step part 211, and therefore, a temperature of the bonding layer 23 is difficult to increase. In such a case, it is preferable to suppress the moving of the heat to the step part 211 by providing the glass layer 24 to thereby make it easy to increase the temperature of the bonding layer 23.

Further, for example, when the material constituting the step part 211 is ceramic, reactivity with the glass layer is lower than the case of the glass, and the bonding strength is weak. In such a case, it is preferable to increase the bonding strength by providing the glass layer 24 to enable a glass-glass reaction. In particular, when the ratio (w₁/h₁) of the width (w₁) to the height (h₁) of the step part is small, the cracks and the peelings are easy to occur, but it is possible to bond in high strength with a low laser output by providing the glass layer 24, and therefore, it is preferable because the cracks and the peelings of the bonding part can be suppressed.

As a glass material for the glass layer formation, for example there can be cited an SiO₂—B₂O₃-REO (RE: alkaline-earth metal, REO: alkaline-earth metal oxide) base, an SiO₂—B₂O₃—PbO base, a B₂O₃—ZnO—PbO base, an SiO₂—ZnO-REO base, an SiO₂-REO base, an SiO₂—PbO base, an SiO₂—B₂O₃—R₂O (R: alkaline metal) base, an SiO₂—B₂O₃—Bi₂O₃ base, an SiO₂—B₂O₃—ZnO base, a B₂O₃—ZnO—Bi₂O₃ base, an SiO₂—ZnO-R₂O base, a B₂O₃—Bi₂O₃ base, and so on.

Besides, the glass layer 24 may contain 1% or less of a ceramic filler to enable the glass-glass reaction, but it is preferable not to contain the ceramic filler. Namely, a glass paste for the glass layer formation may be constituted by only a glass material and an organic component.

A thickness of the glass layer 24 is preferably 1 μm or more. When the thickness of the glass layer 24 is 1 μm or more, the planarity, the heat insulating property, the bonding property remarkably improve. From a viewpoint of improving the planarity, the heat insulating property, and the bonding property, it is more preferably 3 μm or more, and further preferably 5 μm or more. On the other hand, the thickness of the glass layer 24 is preferably 20 μm or less. When the thickness of the glass layer 24 is 20 μm or less, stress and the cracks occurred at the glass layer 24 are reduced. The thickness of the glass layer 24 is more preferably 15 μm or less, and further preferably 10 μm or less.

A surface roughness at a main surface of the glass layer 24 at the lid body 22 side is preferably 0.2 μm or less in an arithmetic mean roughness Ra. When the arithmetic mean roughness Ra is 0.2 μm or less, the local heat generation at the irradiation time of laser light is suppressed because the planarity becomes good, and the bonding strength improves.

Besides, a difference of average thermal expansion coefficients between the glass layer 24 and the package substrate 21 from 50° C. to 350° C. [(the average thermal expansion coefficient of the glass layer)−(the average thermal expansion coefficient of the package substrate)] is preferably −20×10⁻⁷/° C. to 20×10⁻⁷1° C. When the difference of the average thermal expansion coefficients is −20×10⁻⁷/° C. to 20×10⁻⁷/° C., occurrences of warpage and the cracks are suppressed.

Formation of the glass layer 24 is, for example, performed as described below. At first, a burned package substrate 21 is polished to be planarized according to need, and thereafter, the glass paste is coated at a whole surface or at a sealing region of the step part 211, then it is dried to remove an organic solvent. The coating is performed by the printing method such as the screen printing, the gravure printing, or a dispenser, or the like. Next, a coating layer of the glass paste is heated to a temperature of a glass transition point or more of a glass frit to remove a binder component in the coating layer, and thereafter, it is heated to a temperature of a softening point of the glass frit or more to melt the glass frit and burn it to the package substrate. It is thereby possible to form the glass layer 24 at the package substrate 21.

Both of the package substrate 21 and the lid body 22 are constituted by inorganic materials. As the inorganic materials, there can be cited the glass, and a ceramic. Normally, the material of the package substrate 21 is preferably the ceramic from a viewpoint of heat release property, and the material of the lid body 22 is preferably the glass from a viewpoint of transparency, or the like.

As the glass constituting the package substrate 21 and the lid body 22, there can be cited a soda lime glass, a borate glass, a non-alkali glass, a chemically tempered glass, a physically tempered glass, and so on. As the ceramic constituting the package substrate 21 and the lid body 22, there can be cited alumina, silicon nitride, aluminum nitride, silicon carbide, a glass ceramic, and so on. When the ceramic is used for either one of the package substrate 21 or the lid body 22, it is preferable to use the glass for the other member to make the laser light transmit.

The glass ceramic contains the glass and the ceramic, and normally, it is a sintered compact of a glass ceramic composition containing a glass powder and a ceramic powder. A burning temperature of the glass ceramic is low compared to the other ceramics, and therefore, the burning thereof is easy, and it is preferable because a simultaneous burning with silver is possible. Besides, the glass ceramic is preferable because processability thereof is good compared to the other ceramics.

As the glass constituting the glass ceramic, the publicly known glasses used for manufacturing the glass ceramic can be used without particular limitation. As the glass, for example, in mole fraction expressed in terms of oxide, there can be cited one containing SiO₂ for 57% to 65%, B₂O₃ for 13% to 18%, CaO for 9% to 23%, Al₂O₃ for 3% to 8%, and at least one selected from K₂O and Na₂O for 0.5% to 6% as a total.

As for the ceramic constituting the glass ceramic, the publicly known ceramics used for the glass ceramic can be used without particular limitation. As the ceramic, alumina, zirconia, a mixture of alumina and zirconia, or the like can be suitably used. The ceramic is preferably contained for 50 mass % to 70 mass % within a total amount of the glass and the ceramic.

The bonding layer 23 contains the glass and the electromagnetic wave absorbent material as essential components, and normally, it is a burned product of the bonding material containing the glass powder and the electromagnetic wave absorbent material as the essential components. The bonding layer 23 preferably contains a low thermal expansion material according to need.

The electromagnetic wave absorbent material is one converting an electromagnetic wave energy such as the laser light into a thermal energy, and it is added to melt the glass powder at the bonding time. The low thermal expansion material is added according to need to suppress the cracks and the peelings caused by a difference of thermal expansions of the package substrate 21 and the lid body 22, with the bonding layer 23. Normally, the electromagnetic wave absorbent material, the low thermal expansion material are each contained in the bonding layer 23 in a particle state.

As the glass constituting the bonding layer 23, various glasses can be used, but a low-melting point glass is preferable. As the low-melting point glass, there can be cited a bismuth-based glass, a tin phosphate-based glass, a vanadium-based glass, a zinc borate-based glass, and so on. These glasses are each able to obtain high bonding strength because a melting point thereof is low, and enough fluidity can be secured. Among them, the bismuth-based glass, the tin-phosphoric acid glass are preferable, and the bismuth-based glass is more preferable in consideration of the bonding property, reliability, and effects on environment and human body.

The bismuth-based glass preferably contains, in mass fraction expressed in terms of oxide, Bi₂O₃ for 70% to 90%, ZnO for 1% to 20%, B₂O₃ for 2% to 12%. The bonding property becomes good by having the glass composition as stated above.

The bismuth-based glass preferably contains one kind or more of components selected from Al₂O₃, SiO₂, CaO, SrO, and BaO as a component stabilizing the glass. A content as a total of these is preferably 5% or less within a whole of the bismuth-based glass.

The bismuth-based glass is able to further contain one kind or more components selected from Cs₂O, CeO₂, Ag₂O, WO₃, MoO₃, Nb₂O₃, Ta₂O₅, Ga₂O₃, Sb₂O₃, P₂O₅, and SnOₓ as components adjusting the softening temperature, viscosity, and so on. A content as a total of these is preferably 10% or less within the whole of the bismuth-based glass.

As the electromagnetic wave absorbent material constituting the bonding layer 23, a conductive metal oxide is preferable though it is acceptable as long as the electromagnetic wave energy can be converted into the thermal energy. A specific resistance of a film of the conductive metal oxide is preferably 1×10⁻⁴ to 9×10⁻³ Ω·cm when it is independently film-formed. It is possible to efficiently convert the electromagnetic wave energy into the thermal energy according to a conductive oxide material having the specific resistance as stated above.

Note that as the electromagnetic wave absorbent material, a blackish pigment, a transition metal oxide, or the like which have been used up to now can also be used. However, the conductive metal oxide is preferable as the electromagnetic wave absorbent material because a range of a wavelength of the electromagnetic wave capable of absorbing is wider and an amount of the electromagnetic wave capable of absorbing is more than the above.

As the conductive metal oxide, there can be cited a simplex metal oxide, a complex metal oxide, a metal oxide containing dopant, and so on. One kind may be used, or two or more kinds may be combined to be used among the simplex metal oxide, the complex metal oxide, and the metal oxide containing dopant. For example, an ITO (tin-doped indium oxide) may be independently used, or the ITO and an FTO (fluorine-doped tin oxide) may be combined to be used as the conductive metal oxide.

As the conductive metal oxide, a transparent conductive metal oxide is particularly preferable. As the transparent conductive metal oxide, there can be cited an indium-based oxide, a tin-based oxide, a zinc-based oxide, and so on.

As the indium-based oxide, there can be cited the ITO (tin-doped indium oxide), or the like.

As the tin-based oxide, there can be cited the tin-based oxide containing dopant, or the like. As the dopant of the tin-based oxide, there can be cited Sb, Nb, Ta, F, and so on. As the tin-based oxide containing dopant, there can be cited the FTO (fluorine-doped tin oxide), an ATO (antimony-doped tin oxide), and so on.

As the zinc-based oxide, there can be cited the zinc-based oxide containing dopant, or the like. As the dopant of the zinc-based oxide, there can be cited B, Al, Ga, In, Si, Ge, Ti, Zr, Hf, and so on.

As the low thermal expansion material constituting the bonding layer 23, there can be cited one whose linear expansion coefficient is lower than the glass contained in the bonding layer 23. Normally, as the low thermal expansion material, the ceramic is used. As the ceramic, there can be cited magnesia, calcia, silica, alumina, zirconia, zircon, cordierite, zirconium phosphate tungstate, zirconium tungstate, zirconium phosphate, zirconium silicate, aluminum titanate, mullite, eucryptite, spodumene, and so on.

The bonding layer 23 preferably contains the conductive metal oxide for 1 vol % to 60 vol % within a total of the glass, the low thermal expansion material, and the electromagnetic wave absorbent material regardless of presence/absence of the low thermal expansion material. When a content of the conductive metal oxide is 1 vol % or more, an absorption amount of the electromagnetic wave becomes larger, and the generated heat quantity thereby becomes larger. The content of the conductive metal oxide is more preferably 3 vol % or more, and further preferably 5 vol % or more. On the other hand, when the content of the conductive metal oxide is 60 vol % or less, the fluidity at the bonding time becomes high, and therefore, the bonding strength becomes high. The content of the conductive metal oxide is more preferably 45 vol % or less, and further preferably 25 vol % or less.

Besides, when the bonding layer 23 contains the low thermal expansion material, a content of the low thermal expansion material is preferably 1 vol % to 70 vol % within the total of the glass, the low thermal expansion material, and the electromagnetic wave absorbent material. When the content of the low thermal expansion material is 1 vol % or more, the thermal expansion of the bonding layer 23 is effectively improved. The content of the low thermal expansion material is more preferably 10 vol % or more. On the other hand, when the content of the low thermal expansion material is 70 vol % or less, the fluidity at the bonding time becomes high, and therefore, the bonding strength becomes high. The content of the low thermal expansion material is more preferably 50 vol % or less.

Next, a manufacturing method of the package 20 is described. Hereinafter, it is described while citing a case when the glass ceramic being the ceramic is used for the package substrate 21, and a non-lead glass being the glass is used for the lid body 22 as an example.

The package substrate 21 is able to be manufactured by performing, for example, a forming step, a stacking step, and a burning step in this sequence. Hereinafter, each step is concretely described.

In the forming step, at first, a glass powder and a ceramic powder are mixed to manufacture a glass ceramic composition. The glass powder and the ceramic powder are preferably compounded such that the ceramic powder is 50 mass % to 70 mass % within a total amount of the glass powder and the ceramic powder.

After that, a binder, and according to need, a plasticizer, a dispersing agent, a solvent, and so on are added to the glass ceramic composition to manufacture a slurry. Further, this slurry is formed into a sheet state by the doctor blade method or the like, and dried to form a green sheet.

As the binder, there can be cited polyvinylbutyral, an acrylic resin, and so on. As the plasticizer, there can be cited dibutyl phthalate, dioctyl phthalate, butylbenzyl phthalate, and so on. Besides, as the solvent, there can be cited an organic solvent such as toluene, xylene, 2-propanol, 2-butanol.

As the green sheet, for example, a green sheet for a bottom part to form a bottom part of the package substrate 21 and a green sheet for a step part to form the step part 211 and the recessed part 212 of the package substrate 21 are manufactured. As for the green sheet for the step part between these green sheets, a part to be the recessed part 212 is punched, and a part to be the step part 211 is remained.

Adjustments of the width (w₁), the height (h₁), and the ratio (w₁/h₁) at the step part 211 of the package substrate 21 can be performed at a manufacturing time or a process time of the green sheet for the step part. For example, when the part to be the recessed part 212 is punched from the green sheet for the step part, a width of the part which is remained as the step part 211 is adjusted, and thereby, the width (w₁) of the step part 211 can be adjusted. Besides, the number of sheets to be used of the green sheets for the step part, and each thickness are adjusted, and thereby, the height (h₁) of the step part 211 can be adjusted. Note that the adjustments of the width (w₁), the height (h₁), and the ratio (w₁/h₁) at the step part 211 may be performed by methods other than the above.

A conductive paste may be coated on the green sheet for the bottom part and the green sheet for the step part according to need to form wirings or the like by the screen printing method or the like. As the conductive paste, for example, there can be cited one in a paste state in which a vehicle such as ethylcellulose, a solvent according to need, or the like are added to a metal powder whose major constituent is copper, silver, gold, and so on.

In the stacking step, the green sheet for the step part where the part to be the recessed part 212 is punched and the part to be the step part 211 is remained is stacked on the green sheet for the bottom part, and an unburned stack which becomes the package substrate 21 by the burning is manufactured.

In the burning step, the unburned stack is burned to manufacture the package substrate 21. As burning conditions, a burning temperature is preferably 800° C. to 930° C., and a burning time is preferably 10 minutes to 60 minutes in consideration of denseness, productivity, and so on of the glass ceramic. Note that before the burning, it is preferable to perform degreasing to remove the binder or the like. As degreasing conditions, a degreasing temperature is preferably 500° C. to 600° C., and a degreasing time is preferably 1 hour to 10 hours in consideration of removal effect, productivity, and so on of the binder or the like.

In addition, the bonding material used for the formation of the bonding layer 23 is manufactured by mixing the glass powder, the electromagnetic wave absorbent material, and the low thermal expansion material according to need. Further, a resin binder and the vehicle containing an organic solvent are mixed to the bonding material, to manufacture a bonding paste used for the formation of the bonding layer 23. A surface active agent, a thickener, and so on may be added to the bonding paste.

As the resin binder, there can be used acrylic resins such as methylcellulose, carboxymethylcellulose, oxyethylcellulose, benzylcellulose, propylcellulose, methacrylate ester, methyl(meta)acrylate, ethyl(meta)acrylate, butyl(meta)acrylate, 2-hydroxyethylmethacrylate, ethylcellulose, a polyethyleneglycol derivative, nitrocellulose, polymethylstyrene, polyethylenecarbonate, and so on.

As the organic solvent, there can be used N,N′-dimethylformamide (DMF), α-terpineol, higher alcohol, γ-butyrolactone (γ-BL), tetraline, ethylcarbitolacetate, butylcarbitolacetate, methylethylketone, ethylacetate, isoamylacetate, diethyleneglycolmonoethylether, diethyleneglycolmonoethyletheracetate, benzylalcohol, toluene, 3-methoxy-3-methylbutanol, triethyleneglycolmonomethylether, triethyleneglycoldimethylether, dipropyleneglycolmonomethylether, dipropyleneglycolmonobutylether, tripropyleneglycolmonomethylether, tripropyleneglycolmonobutylether, propylenecarbonate, dimethylsulfoxide (DMSO), N-methyl-2-pyrrolidone, and so on. In particular, α-terpineol is preferable because it is high viscosity, and solubilities of the resin binder or the like are also good.

Next, the bonding paste is coated on a part of a surface of the lid body 22 which is bonded by the bonding layer 23, and thereafter, it is dried to remove the organic solvent. The coating is performed by the printing methods such as the screen printing, the gravure printing, or the dispenser, or the like. Besides, the drying is preferably performed at a drying temperature of 120° C. or more and a drying time for 5 minutes or more though they are different dependent on kinds of the organic solvent. The organic solvent is fully removed by the drying, and thereby, the resin binder is easy to be removed at the burning time.

After that, the bonding paste provided at the lid body 22 is melted (pre-burning) and solidified, to form a bonding material layer to be the bonding layer 23 at the lid body 22. As melting conditions, at a temperature of 450° C. or more and a time for 10 minutes or more are preferable. Besides, the melting condition is preferably a condition where a crystal phase does not precipitate at the bonding material layer.

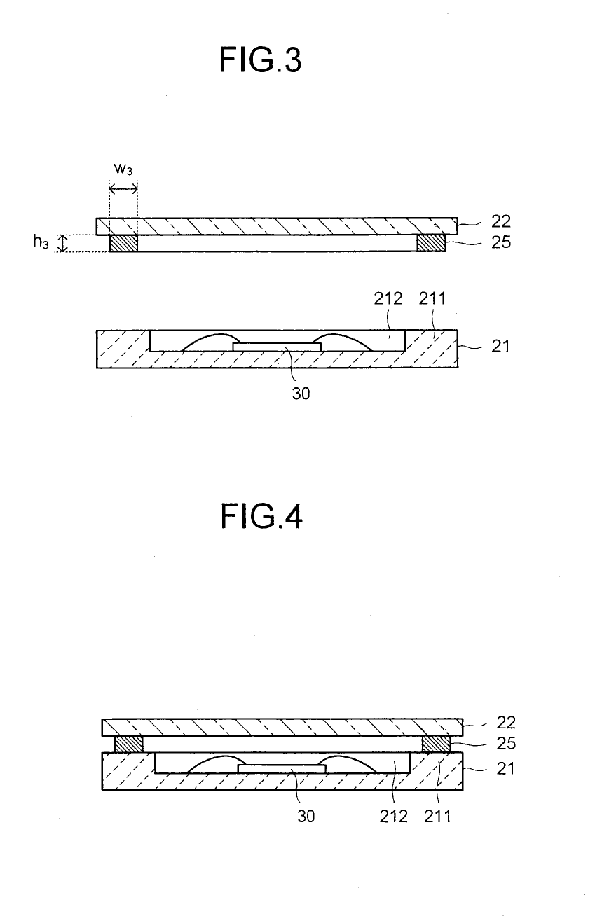

After that, as illustrated in FIG. 3 and FIG. 4, the package substrate 21 where the electronic element 30 is accommodated at the recessed part 212, and the lid body 22 where a bonding material layer 25 is formed are stacked such that a surface side having the recessed part 212 and the step part 211 and a surface side having the bonding material layer 25 face. The step part 211 of the package substrate 21 and the bonding material layer 25 of the lid body 22 are thereby brought into contact. Here, FIG. 3 illustrates a state before stacking, and FIG. 4 illustrates a state after stacking.

Note that a ratio ((w₁/h₁)/(w₃·h₃)) of the ratio (w₁/h₁) of the width (w₁) to the height (h₁) of the step part 211 to a product (w₃·h₃) of a width (w₃) and a height (h₃) of the bonding material layer 25 is preferably 100 [mm⁻²] or more. Here, the height (h₃) of the bonding material layer 25 is a length in a thickness direction of the bonding material layer 25. The width (w₃) of the bonding material layer 25 is a length in a vertical direction relative to the thickness direction of the bonding material layer 25.

When the ratio ((w₁/h₁)/(w₃·h₃)) is less than 100 [mm⁻²], a cross-sectional area of the bonding material layer 25 is relatively large, and therefore, the heat generated at the bonding material layer 25 at the bonding time is difficult to go away to the other parts through the step part 211, and is easy to go away to the lid body 22. When the ratio ((w₁/h₁)/(w₃·h₃)) is 100 [mm⁻²] or more, the cross-sectional area of the bonding material layer 25 is relatively small, and therefore, it is preferable because the heat generated at the bonding material layer 25 at the bonding time is easy to go away to the other parts through the step part 211.

The ratio ((w₁/h₁)/(w₃·h₃)) is preferably 200 [mm²] or more, more preferably 300 [mm⁻²] or more, and further preferably 500 [mm⁻²] or more from a viewpoint that the heat generated at the bonding material layer 25 at the bonding time is made easy to go away to the other parts through the step part 211. On the other hand, when the ratio ((w₁/h₁)/(w₃·h₃)) becomes excessively high, there is a possibility in which bonding strength becomes insufficient, therefore, it is preferably 5000 [mm⁻²] or less, more preferably 2500 [mm⁻²] or less, and further preferably 1000 [mm⁻²] or less.

The width (w₃) of the bonding material layer 25 is preferably 0.1 mm or more, more preferably 0.15 mm or more, and further preferably 0.2 mm or more from a viewpoint of securing printability of the bonding material layer 25 and the bonding strength of the bonding layer 23. Besides, the width (w₃) of the bonding material layer 25 is preferably 1.0 mm or less, more preferably 0.8 mm or less, and further preferably 0.5 mm or less from a viewpoint of reducing a heat quantity moving from the bonding material layer 25 to the other parts at the bonding time.

The height (h₃) of the bonding material layer 25 is preferably 1 μm or more, more preferably 3 μm or more, and further preferably 5 μm or more from a viewpoint of securing the bonding strength. Besides, the height (h₃) of the bonding material layer 25 is preferably 50 μm or less, more preferably 25 μm or less, and further preferably 15 μm or less from the viewpoint of reducing the heat quantity moving from the bonding material layer 25 to the other parts at the bonding time.

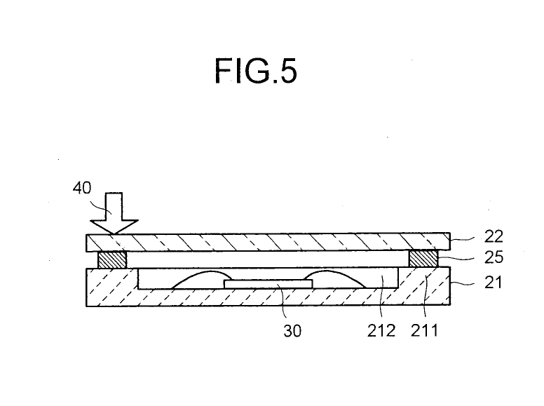

Next, as illustrated in FIG. 5, a laser light 40 is irradiated through the lid body 22, and thereby, the bonding material layer 25 is melted, solidified, and burned. For example, when the bonding material layer 25 is annularly provided along the outer edge part of the lid body 22, the laser light 40 scans to make a circuit along the bonding material layer 25 to burn. The package substrate 21 and the lid body 22 are thereby bonded by the bonding layer 23 formed by the burning of the bonding material layer 25.

At this time, the step part 211 has a predetermined shape, and more preferably, the bonding layer 23 has a predetermined shape, and thereby, the occurrences of the cracks and the peelings at the bonding part are suppressed. The package 20 with high airtightness is thereby manufactured.

As the laser light 40, a semiconductor laser, a carbon dioxide gas laser, an excimer layer, an YAG laser, an HeNe laser, and so on are used. A heating temperature of the bonding material layer 25 is preferably a temperature T₁ (=T+80° C.) or more and a temperature T₂ (=T+550° C.) or less relative to a softening temperature T (° C.) of the glass powder. Here, the softening temperature T of the glass powder is a temperature where it is softened and flows but is not crystallized. Besides, the heating temperature of the bonding material layer 25 is measured by a radiation thermometer.

When the bonding material layer 25 does not reach the temperature T₁, only a surface part of the bonding material layer 25 is melted, and there is a possibility in which the package substrate 21 and the bonding layer 23 are not enough bonded. On the other hand, when the bonding material layer 25 exceeds the temperature T₂, the cracks are easy to occur at the package substrate 21, the lid body 22, and the bonding layer 23.

A scanning speed of the laser light 40 is preferably 1 min/sec to 20 mm/sec. When the scanning speed of the laser light 40 is 1 mm/sec or more, the productivity of the package 20 becomes good. On the other hand, when the scanning speed of the laser light 40 exceeds 20 mm/sec, laser output becomes high, and therefore, a residual stress is easy to be generated, and the cracks are easy to occur at the package substrate 21, the lid body 22, and the bonding layer 23.

The output of the laser light 40 is preferably within a range of 10 W to 100 W. When the output of the laser light 40 is less than 10 W, there is a possibility in which the bonding material layer 25 is not uniformly heated. On the other hand, when the output of the laser light 40 exceeds 100 W, the package substrate 21, the lid body 22, and the bonding layer 23 are excessively heated, and the cracks are easy to occur.

A beam shape of the laser light 40 (namely, a shape of an irradiation spot) is generally circular, but it may be elliptical or the like in which a longitudinal direction of the bonding material layer 25 is a major axis direction. According to the elliptical beam shape, it is easy to secure an irradiation area of the laser light 40, and it is possible to heighten the scanning speed of the laser light 40 to reduce the burning time.

### EXAMPLES

Hereinafter, the present invention is described in detail based on examples. Note that the present invention is not limited to the following examples.

### Example 1

As each component of the bonding material, the followings were prepared. As the glass powder, the bismuth-based glass powder (softening temperature: 410° C.) having a composition of, in mass fraction, Bi₂O₃ for 83%, ZnO for 11%, B₂O₃ for 5%, Al₂O₃ for 1% was prepared. As the electromagnetic wave absorbent material, the ATO (antimony-doped tin oxide) powder was prepared. As the low thermal expansion material, the cordierite powder was prepared. A D₅₀ (median size) of the glass powder is 1.2 μm, a D₅₀ of the electromagnetic wave absorbent material is 1.0 μm, and a D₅₀ of the low thermal expansion material is 4.3 μm.

All of the D₅₀ of the glass powder, the electromagnetic wave absorbent material, and the low thermal expansion material were each measured by using a particle size analyzer (manufactured by Nikkiso Co., Ltd., Microtrac HRA). Measurement conditions were set to be a measurement mode: HRA-FRA mode, Particle Transparency: Yes, Spherical Particles: No, Particle Refractive index: 1.75, Fluid Refractive index: 1.33. A slurry in which each powder was dispersed in water and hexametaphosphoric acid was dispersed by ultrasonic wave, and thereafter, the D₅₀ was measured.

Next, respective components were mixed, and the bonding material was manufactured. Proportions of respective components were set to be: the glass powder for 60.7 vol %, the electromagnetic wave absorbent material for 13.2 vol %, the low thermal expansion material for 26.1 vol %. A linear expansion coefficient (50° C. to 450° C.) of the bonding material is 66×10⁻⁷/° C.

The linear expansion coefficient (50° C. to 450° C.) of the bonding material was measured as follows. At first, the bonding material was heated and burned for 10 minutes at a temperature range from the softening temperature plus 30° C. to a crystallization temperature minus 30° C. of the glass powder to manufacture the sintered compact. This sintered compact was polished, and a sample in a round bar shape with a length of 20 mm, and a diameter of 5 mm was manufactured. After that, the linear expansion coefficient of this sample was measured by TMA8310 manufactured by Rigalcu Co., Ltd. The linear expansion coefficient (50° C. to 450° C.) is an average linear expansion coefficient within a temperature range of 50° C. to 450° C. measured as stated above.

Further, the bonding material for 85 mass % and the vehicle for 15 mass % were mixed, and thereafter, it was passed through a triple-roll mill to manufacture the bonding paste. For the vehicle, a mixture of ethylcellulose as an organic binder for 5 mass % and diethyleneglycolmono-2-ethylhexylether as the solvent for 95 mass % was used.

In addition, as a lid body, a glass substrate (size: 7 mm×7 mm×0.2 mmt) constituted by a borosilicate glass (linear expansion coefficient (25° C. to 400° C.): 64×10⁻⁷/° C.) was prepared. At a surface of the lid body, the bonding paste was annularly coated by the screen printing at an outer edge part. A screen plate with a mesh size of 180 (opening: 91 μm), and a emulsion thickness of 10 μm was used for the screen printing.

After the screen printing, the bonding paste was dried under a condition of 120° C. for 10 minutes, further was pre-burned under a condition of 480° C. for 10 minutes to form a bonding material layer at a surface of the lid body.

After that, a width (w₃) of the bonding material layer was measured by using an optical microscope from a rear surface side of the lid body where the bonding material layer was not formed. As the width (w₃) of the bonding material layer, a minimum distance excluding printing blur and unevenness was measured as for each of arbitrary four points, and an average value thereof was found. A height (h₃) of the bonding material layer was measured by using SURFCOM (manufactured by Tokyo Seimitsu Co., Ltd., 1400D). As the height (h₃) of the bonding material layer, a thickness of the bonding material layer was measured at each of arbitrary four points, and an average value thereof was found.

Note that the width (w₃) of the bonding material layer seldom change before and after the burning performed subsequently (before and after the bonding between a package substrate and the lid body). Therefore, the width (w₃) of the bonding material layer is able to equate with a width (w₂) of a bonding layer. Similarly, the height (h₃) of the bonding material layer seldom change before and after the burning performed subsequently (before and after the bonding between the package substrate and the lid body). Therefore, the height (h₃) of the bonding material layer is able to equate with a height (h₂) of the bonding layer.

Besides, in addition, as the package substrate, a glass substrate (size: 7 mm×7 mm×1.3 mmt) constituted by a borosilicate glass (linear expansion coefficient (25° C. to 400° C.): 64×10⁻⁷/° C.) in which a recessed part of 5 mm×5 mm×1 mm was formed at an inside thereof and a step part in a frame state with a width (w₁) of 1 mm and a height (h₁) of 1 mm was held, was prepared.

After that, the package substrate having the recessed part and the lid body where the bonding material layer was formed were stacked. Further, a laser light (semiconductor laser) with a wavelength of 808 nm, a spot diameter of 1.6 mm, and an output of 23 W was irradiated at a scanning speed of 4 mm/sec for the bonding material layer through the lid body, to make it the bonding layer. Note that an intensity distribution of the laser light is not constantly formed, and the laser light having the intensity distribution of a projecting shape was used. As the spot diameter, a radius of a contour line where the laser intensity becomes 1/e² was used. A package in which the package substrate and the lid body are bonded by the bonding layer was thereby manufactured.

### Examples 2 to 10

As illustrated in Table 1, packages of examples 2 to 4 were manufactured by each bonding the package substrate and the lid body by the bonding layer as same as the example 1 except that the width (w₁) and the height (h₁) of the step part of the package substrate and the width (w₃) and the height (h₃) of the bonding material layer were changed.

Besides, packages of examples 5 to 10 were manufactured by each bonding the package substrate and the lid body by the bonding layer as same as the example 1 except that the material of the package substrate was changed to ceramic, and the width (w₁) and the height (h₁) of the step part and the width (w₃) and the height (h₃) of the bonding material layer were changed.

Note that the ceramic constituting the package substrate was the glass ceramic being the sintered compact of the glass ceramic composition containing the glass powder and the ceramic powder.

### Examples 11 to 12

Packages of examples 11 and 12 were manufactured by bonding the package substrate and the lid body by the bonding layer as same as the example 5 except that a glass layer was provided between the step part of the package substrate and the bonding layer, and the width (w₁) and the height (h₁) of the step part and the width (w₃) and the height (h₃) of the bonding material layer were changed.

Note that the glass layer is constituted by SiO₂—B₂O₃—ZnO based glass frit, a thickness thereof is 13 μm, and the arithmetic mean roughness Ra is 0.2 μm. Besides, a difference of average thermal expansion coefficients between the glass layer and the package substrate from 50° C. to 350° C. [(the average thermal expansion coefficient of the glass layer)−(the average thermal expansion coefficient of the package substrate)] is 7×10⁻⁷/° C. Here, the thickness and the arithmetic mean roughness Ra were measured by SURFCOM (manufactured by Tokyo Seimitsu Co., Ltd., 1400D), and the average thermal expansion coefficient was measured by TMA8310 manufactured by Rigaku Co., Ltd.

### Comparative Example 1

As illustrated in Table 1, a package of a comparative example 1 was manufactured by bonding the package substrate and the lid body by the bonding layer as same as the example 1 except that the material of the package substrate was changed to ceramic, and the width (w₁) and the height (h₁) of the step part and the width (w₃) and the height (h₃) of the bonding material layer were changed.

Next, as for the packages of the examples and the comparative example, presence/absence of peelings between the package substrate and the bonding layer and between the lid body and the bonding layer, cracks at the package substrate, the lid body, and the bonding layer were observed by using the optical microscope. In Table 1, it is described as “none” for one in which the package without peelings and cracks at any part could be manufactured, and a content of the defect was described as for one in which only the package with the peelings or the cracks was manufactured.

Besides, in Table 1, a ratio in which the peeling and the cracks were not recognized was represented as a sealing yield when 20 pieces of packages were each manufactured under the same condition as for each of the packages of the examples and the comparative example. Here, when the material of the package substrate is the glass, all of the sealing yields become 80% or more. On the other hand, when the material of the package substrate is the ceramic, and when the glass layer is not provided, a lot of peelings and cracks occur, and the sealing yield is easy to be lowered to 20% to 30%. However, the glass layer is provided, and thereby, the peelings and the cracks are suppressed, and the sealing yield becomes 80% or more.

TABLE 1

| | Package substrate | | | | | | Bonding material | | | | | |
|---|---|---|---|---|---|---|---|---|---|---|---|---|
| | | Step part | | | | | layer | | (w₁/h₁)/ | Laser | | Sealing |
| | | SIZE | Width | Height | w₁/h₁ | Glass | Width | Height | (w₃ · h₃) | output | Peelings | yield |
| | Material | [mm²] | w₁ [mm] | h₁ [mm] | [—] | layer | w₃ [mm] | h₃ [mm] | [mm⁻²] | [W] | Cracks | [%] |
| Example 1 | Glass | 7 × 7 | 1.0 | 1.0 | 1.0 | Absent | 0.41 | 0.015 | 163 | 23 | None | 85 |
| Example 2 | Glass | 7 × 7 | 1.0 | 0.3 | 3.3 | Absent | 0.41 | 0.015 | 542 | 23 | None | 90 |
| Example 3 | Glass | 7 × 7 | 2.0 | 1.0 | 2.0 | Absent | 0.37 | 0.015 | 360 | 23 | None | 90 |
| Example 4 | Glass | 7 × 7 | 1.0 | 1.0 | 1.0 | Absent | 0.23 | 0.015 | 290 | 40 | None | 90 |
| Example 5 | Ceramic | 7 × 7 | 1.4 | 0.9 | 1.6 | Absent | 0.41 | 0.020 | 190 | 21 | None | 20 |
| Example 6 | Ceramic | 7 × 7 | 2.5 | 0.2 | 12.5 | Absent | 0.31 | 0.020 | 2016 | 21 | None | 80 |
| Example 7 | Ceramic | 7 × 7 | 1.8 | 0.2 | 9.0 | Absent | 0.34 | 0.020 | 1324 | 20 | None | 80 |
| Example 8 | Ceramic | 7 × 7 | 2.5 | 0.6 | 4.2 | Absent | 0.36 | 0.020 | 579 | 20 | None | 80 |
| Example 9 | Ceramic | 7 × 7 | 1.8 | 0.9 | 2.0 | Absent | 0.35 | 0.020 | 286 | 20 | None | 30 |
| Example 10 | Ceramic | 25 × 30 | 4.0 | 0.6 | 6.7 | Absent | 0.40 | 0.015 | 1111 | 20 | None | 20 |
| Example 11 | Ceramic | 7 × 7 | 1.8 | 0.9 | 2.0 | Present | 0.35 | 0.020 | 286 | 20 | None | 90 |
| Example 12 | Ceramic | 25 × 30 | 4.0 | 0.6 | 6.7 | Present | 0.40 | 0.015 | 1111 | 20 | None | 85 |
| Comparative | Ceramic | 7 × 7 | 0.8 | 1.5 | 0.5 | Absent | 0.42 | 0.020 | 63 | 21 | Cracks | 0 |
| Example 1 | | | | | | | | | | | | |

Besides, as for each of the packages of the examples 7 and 8, a temperature cycling test was performed (1 cycle: −40° C. to 150° C., 200 cycles). Presence/absence of peelings between the package substrate and the bonding layer and between the lid body and the bonding layer, cracks at the package substrate, the lid body, and the bonding layer were observed before and after the temperature cycling test. As a result, the peelings and the cracks were not recognized at any part.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A package substrate, comprising:
a recessed part; and
a step part disposed at a periphery of the recessed part,
wherein a lid body is bonded to the step part to cover the recessed part via a bonding layer containing a glass and an electromagnetic wave absorbent material,
wherein a ratio (w₁/h₁) of a width (w₁) to a height (h₁) of the step part is 1.0 or more.

2. A package, comprising:
a package substrate including a recessed part and a step part disposed at a periphery thereof, and a ratio (w₁/h₁) of a width (w₁) to a height (h₁) of the step part being 1.0 or more;
a lid body disposed to face the package substrate to cover the recessed part; and
a bonding layer bonding the package substrate and the lid body at the step part, the bonding layer containing a glass and an electromagnetic wave absorbent material.

3. The package according to claim 2,
wherein a ratio ((w₁/h₁)/(w₂·w₂)) of the ratio (w₁/h₁) to a product (w₂·h₂) of a width (w₂) and a height (h₂) of the bonding layer is 100 [mm⁻²] or more.

4. The package according to claim 2,
wherein the step part has an annular shape along an outer edge part of the package substrate.

5. The package according to claim 2,
wherein the package substrate and the lid body are constituted by different materials.

6. The package according to claim 5,
wherein the package substrate is constituted by a ceramic, and the lid body is constituted by a glass.

7. The package according to claim 6,
wherein the ceramic is a glass ceramic.

8. The package according to claim 2,
wherein the step part includes a glass layer at a surface thereof.

9. The package according to claim 8,
wherein a thickness of the glass layer is 1 μm to 20 μm.

10. The package according to claim 8,
wherein a surface roughness of the glass layer is 0.2 μm or less in an arithmetic mean roughness Ra.

11. The package according to claim 8,
wherein a difference of average thermal expansion coefficients between the glass layer and the package substrate from 50° C. to 350° C. [(the average thermal expansion coefficient of the glass layer)−(the average thermal expansion coefficient of the package substrate)] is −20×10⁻⁷/° C. to 20×10⁻⁷/° C.

12. An electronic device, comprising:
the package according to claim 2; and
an electronic element accommodated in the package.
